(19) United States
(12) Patent Application Publication
(10) Pub. No.: US 2024/0162385 A1
(43) Pub. Date: May 16, 2024

(54) NITRIDE SEMICONDUCTOR LIGHT-EMITTING ELEMENT

(71) Applicant: ASAHI KASEI KABUSHIKI KAISHA, Tokyo (JP)

(72) Inventor: Tomoya YAMADA, Tokyo (JP)

(73) Assignee: ASAHI KASEI KABUSHIKI KAISHA, Tokyo (JP)

(21) Appl. No.: 18/284,400

(22) PCT Filed: Mar. 23, 2022
(86) PCT No.: PCT/JP2022/013643

§ 371 Date: Sep. 27, 2023

(30) Foreign Application Priority Data
Mar. 29, 2021 (JP) 2021-055616

(51) Int. Cl. H01L 33/32; H01L 33/38

(52) U.S. Cl. CPC H01L 33/32; H01L 33/38

(57) ABSTRACT

The present invention provides a nitride semiconductor light-emitting element that can suppress current concentration without increasing drive voltage and manufacturing steps. A nitride semiconductor light-emitting element includes n-type electrodes arranged so that contact interfaces with a first nitride semiconductor layer are first contact regions extending in a first direction and p-type electrodes arranged so that contact interfaces with a second nitride semiconductor layer are second contact regions extending in the first direction, lengths of line segments of perimeter lines of the first contact regions parallel to the first direction being shorter than lengths of line segments of perimeter lines of the second contact regions parallel to the first direction and facing the first contact regions.

### TECHNICAL FIELD

The present invention relates to a nitride semiconductor light-emitting element.

### BACKGROUND ART

Nitride semiconductor light-emitting elements include, for example, a substrate, and an n-type nitride semiconductor layer arranged on the substrate, a nitride semiconductor light-emitting layer and a p-type nitride semiconductor light-emitting layer arranged on a part of the n-type nitride semiconductor layer, an n-type electrode on the n-type nitride semiconductor layer, and a p-type electrode arranged on the p-type nitride semiconductor layer.

In nitride semiconductor light-emitting elements, current flowing between the p-type electrode and n-type electrode tends to flow to a path where resistance is lowered, and therefore the current flows partially to an end portion of the p-type electrode on a side close to the n-type electrode, causing current concentration. Particularly, when the n-type nitride semiconductor layer has a thin film thickness or when an AlGaN layer is used as the n-type nitride semiconductor layer, sheet resistance of the n-type nitride semiconductor layer increases, which tends to significantly cause current concentration.

The current concentration is a factor that causes deteriorated characteristics of nitride semiconductor light-emitting elements, such as reduced luminance efficiency and reduced reliability of the light-emitting elements.

PTL 1 examines alleviation of the current concentration by arranging a high-resistance layer on a surface of a p-type semiconductor layer to adjust resistance balance of an element.

### CITATION LIST

### Patent Literature

PTL 1: JP 2014-96460 A

### SUMMARY OF INVENTION

### Technical Problem

In nitride semiconductor light-emitting elements, current flowing between the p-type electrode and the n-type electrode tends to flow to a path with lowered resistance. Therefore, the current flows partially to an end portion of the p-type electrode on a side close to the n-type electrode, resulting in current concentration. Particularly, when film thickness of the n-type nitride semiconductor layer is thin or when an AlGaN layer is used as the n-type nitride semiconductor layer, the n-type nitride semiconductor layer has increased sheet resistance, whereby current concentration tends to occur significantly. The current concentration is what causes the deterioration of characteristics of nitride semiconductor light-emitting elements, such as reduction of luminous efficiency and reduction of reliability of the light-emitting elements.

PTL 1 examines alleviation of the current concentration by arranging the high-resistance layer on the surface of the p-type semiconductor layer to adjust the resistance balance of the element. However, in a technology disclosed in PTL 1, arranging the high-resistance layer on the surface of the p-type semiconductor layer increases drive voltage, leading to reduced luminous efficiency. In addition, manufacturing cost will increase due to an additional manufacturing step.

It is an object of the present invention to provide a nitride semiconductor light-emitting element that can suppress current concentration without increasing drive voltage or manufacturing steps.

### Solution to Problem

In order to achieve the above object, it has been found that by devising the arrangement of semiconductor layers and a first conductivity type electrode and a second conductivity type electrode, uniform current diffusion and uniform light emission can be obtained without increasing manufacturing cost, whereby the present invention has been made.

Specifically, a nitride semiconductor light-emitting element according to one aspect of the present invention has either or both of the following configuration requirements (a) or/and (b):
(a) a structure that includes a first electrode arranged so that a contact interface with a first nitride semiconductor layer is a first contact region extending in a first direction and a second electrode arranged so that a contact interface with a second nitride semiconductor layer is a second contact region extending in the first direction, and in which, in plan view, a length of a first line segment of a perimeter line of the first contact region parallel to the first direction is shorter than a length of a second line segment of a perimeter line of the second contact region parallel to the first direction and facing the first contact region; and
(b) a structure that includes a third electrode arranged so that a contact interface with the second nitride semiconductor layer provided in the second semiconductor laminated portion is a third contact region extending in the first direction, and sandwiching the first electrode together with the second electrode, in which, in the plan view, a length of a third line segment of the perimeter line of the first contact region parallel to the first direction and facing the first line segment is equal to or shorter than a length of a fourth line segment of a perimeter line of the third contact region parallel to the first direction and facing the first contact region.

### Advantageous Effects of Invention

According to the one aspect of the present invention, current concentration can be suppressed without increasing drive voltage or manufacturing steps.

### BRIEF DESCRIPTION OF DRAWINGS

FIG. 1 is a schematic cross-sectional view illustrating an example of a schematic configuration of a nitride semiconductor light-emitting element according to one embodiment of the present invention;

FIG. 2 is a schematic plan view illustrating one example of contact regions with semiconductor laminated portions and electrodes provided in the nitride semiconductor light-emitting element according to the one embodiment of the present invention;

FIG. 3 is a schematic plan view illustrating the one example of the contact regions with the semiconductor laminated portions and the electrodes provided in the nitride semiconductor light-emitting element according to the one embodiment of the present invention, and is an enlarged view enlarging a dashed line α illustrated in FIG. 2;

FIG. 4 is a schematic plan view illustrating one example of arrangement locations of the semiconductor laminated portions provided in the nitride semiconductor light-emitting element according to the one embodiment of the present invention;

FIG. 5 is a schematic plan view illustrating one example of contact regions with semiconductor laminated portions and electrodes provided in a nitride semiconductor light-emitting element according to Example 2 of the one embodiment of the present invention;

FIG. 6 is a schematic plan view illustrating one example of contact regions with semiconductor laminated portions and electrodes provided in a nitride semiconductor light-emitting element according to Example 3 of the one embodiment of the present invention;

FIG. 7 is a schematic plan view illustrating contact regions with semiconductor laminated portions and electrodes provided in a nitride semiconductor light-emitting element according to Comparative Example;

FIG. 8 is a diagram illustrating a nitride semiconductor light-emitting element according to Modification 1 of the one embodiment of the present invention, and is a schematic plan view illustrating one example of contact regions with semiconductor laminated portions and an electrode;

FIG. 9 is a diagram illustrating a nitride semiconductor light-emitting element according to Modification 2 of the one embodiment of the present invention, and is a schematic plan view illustrating one example of contact regions with semiconductor laminated portions and an electrode; and

FIG. 10 is a diagram illustrating a nitride semiconductor light-emitting element according to Modification of the one embodiment of the present invention, and is a schematic plan view illustrating one example of contact regions with semiconductor laminated portions and electrodes.

### DESCRIPTION OF EMBODIMENTS

### Embodiments

The present invention is described below through embodiments, but the following embodiments do not limit the present invention according to the claims. Additionally, not all combinations of features described in the embodiments are essential for solution of the present invention.

[Entire Configuration]

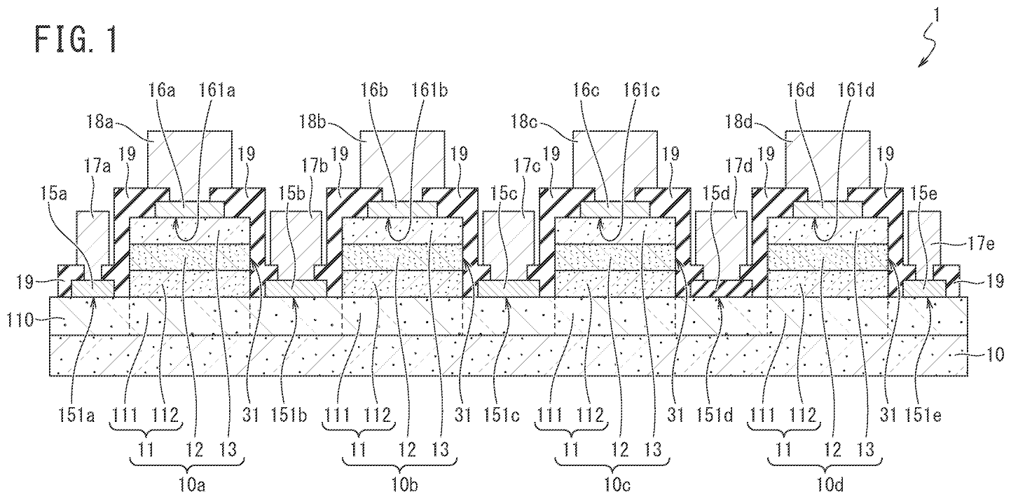

A nitride semiconductor light-emitting element 1 illustrated in FIG. 1 is an element that emits ultraviolet light with a peak wavelength range of 300 nm or less. As illustrated in FIG. 1, the nitride semiconductor light-emitting element 1 includes a substrate 10, semiconductor laminated portions 10a, 10b, 10c, and 10d, a protective film 19, n-type electrodes (an example of a first electrode) 15a, 15b, 15c, 15d, and 15e, p-type electrodes (an example of a second electrode and a third electrode) 16a, 16b, 16c, and 16d, and pad electrodes 17a, 17b, 17c, 17d, 17e, 18a, 18b, 18c, and 18d.

Here, for example, when the n-type electrode 15b corresponds to the first electrode, for example, the p-type electrode 16a corresponds to the second electrode, and for example, the p-type electrode 16b corresponds to the third electrode. Additionally, for example, when the n-type electrode 15c corresponds to the first electrode, for example, the p-type electrode 16b corresponds to the second electrode, and for example, the p-type electrode 16c corresponds to the third electrode. Furthermore, for example, when the n-type electrode 15d corresponds to the first electrode, for example, the p-type electrode 16c corresponds to the second electrode, and for example, p-type electrode 16d corresponds to the third electrode.

[Details of Each Layer]

<Substrate>

The substrate 10 is not particularly limited as long as a first nitride semiconductor layer 11 of a first conductivity type can be formed on the substrate 10. Specific examples of the substrate 10 includes sapphire, silicon (Si), silicon carbide (SiC), magnesium oxide (MgO), gallium oxide (Ga₂O₃), zinc oxide (ZnO), gallium nitride (GaN), indium nitride (InN), aluminum nitride (AlN), a mixed crystal substrate thereof, and the like.

From a viewpoint that a lattice constant difference from the n-type nitride semiconductor layer formed on an upper layer side of the substrate 10 is small and threading dislocation can be reduced by growing in a lattice-matched system, and from a viewpoint that lattice strain for hole gas formation can be increased, a single crystal substrate including a nitride semiconductor bulk material, such as GaN, AlN, or AlGaN, or a nitride semiconductor layer (also referred to as a template) of GaN, AlN, AlGaN, or the like grown on a certain material is preferably used as the substrate 10. The substrate 10 may contain impurities.

Additionally, from a viewpoint of light extraction improvement, a surface of the substrate 10 on an opposite side of a surface thereof where the semiconductor laminated portions 10a to 10d are formed may be processed.

<Semiconductor Laminated Portions>

As illustrated in FIG. 1, each of the semiconductor laminated portions (an example of a first semiconductor laminated portion or a second semiconductor laminated portion) 10a to 10d included in the nitride semiconductor light-emitting element 1, includes an n-type first nitride semiconductor layer 11 formed on the substrate 10, a nitride semiconductor light-emitting layer 12 formed on a part of the first nitride semiconductor layer 11, and a p-type second nitride semiconductor layer 13 formed on the nitride semiconductor light-emitting layer 12.

The nitride semiconductor light-emitting element 1 includes a base portion 110 made of a nitride semiconductor formed over substantially the entire surface of the substrate 10. The first nitride semiconductor layer 11 is composed of the base portion 110 and a nitride semiconductor film 112 arranged on the nitride semiconductor film 111 that is a part of the base portion 110 corresponding to each of arrangement positions of the semiconductor laminated portions 10a to 10d. The nitride semiconductor light-emitting layer 12 is arranged on the nitride semiconductor film 112. For ease of understanding, in FIG. 1, the part of the base portion 110 corresponding to the nitride semiconductor film 111 is illustrated by dividing with dashed lines.

Here, among the semiconductor laminated portions 10a to 10d, one of adjacent two semiconductor laminated portions corresponds to the first semiconductor laminated portion, and the other one of the adjacent two semiconductor laminated portions corresponds to the second semiconductor laminated portion. For example, when the semiconductor laminated portion 10a corresponds to the first semiconductor laminated portion, for example, the semiconductor laminated portion 10b corresponds to the second semiconductor laminated portion. Additionally, for example, when the semiconductor laminated portion 10b corresponds to the first semiconductor laminated portion, for example, the semiconductor laminated portion 10c corresponds to the second semiconductor laminated portion. Furthermore, for example, when the semiconductor laminated portion 10c corresponds to the first semiconductor laminated portion, for example, the semiconductor laminated portion 10d corresponds to the second semiconductor laminated portion.

The nitride semiconductor light-emitting element 1 according to the present embodiment may further include layers for achieving other features, such as a buffer layer, a barrier layer, and a contact layer, in addition to the above layers.

Each of the semiconductor laminated portions 10a to 10d has a mesa structure composed of the nitride semiconductor film 111 and a mesa portion 31 arranged to protrude on the nitride semiconductor film 111. The mesa portion 31 includes the nitride semiconductor film 112, the nitride semiconductor light-emitting layer 12, and the second nitride semiconductor layer 13. The method for forming the mesa structure is not particularly limited, but can be formed by laminating each layer using a film forming device for molecular beam epitaxy (MBE), metal organic chemical vapor deposition (MOCVD), or the like on the substrate 10, forming a mask pattern by photolithography, and etching a desired region by dry etching or wet etching.

<N-Type First Nitride Semiconductor Layer>

As illustrated in FIG. 1, the n-type first nitride semiconductor layer 11 may be provided directly on the substrate 10. The n-type first nitride semiconductor layer 11 provided in each of the semiconductor laminated portions 10a to 10d may have a layer thickness of, for example, from 200 nm to 1000 nm. Alternatively, a layer other than the n-type first nitride semiconductor layer 11 may be provided on the substrate 10, and the n-type first nitride semiconductor layer 11 may be provided on the layer. For example, a buffer layer may be provided on the substrate 10, an n-type AlGaN layer may be provided as the n-type first nitride semiconductor layer 11 on the buffer layer, and the nitride semiconductor light-emitting layer 12 may be provided on the n-type AlGaN layer.

The n-type first nitride semiconductor layer 11 provided in each of the semiconductor laminated portions 10a to 10d may be formed of, for example, AlₓGa₍₁₋ₓ₎N (x>0). The n-type first nitride semiconductor layer 11 is not particularly limited as long as it is a nitride semiconductor, but is preferably a mixed crystal of AlN, GaN, and InN from a viewpoint of achievement of high luminous efficiency. The n-type first nitride semiconductor layer 11 may contain group V elements such as phosphorous (P), arsenic (As), and antimony (Sb), and impurities such as carbon (C), hydrogen (H), fluorine (F), oxygen (O), magnesium (Mg), and Si.

<Light-Emitting Layer>

As illustrated in FIG. 1, the nitride semiconductor light-emitting layer 12 may be provided directly on the nitride semiconductor film 112 forming the mesa portion 31. Alternatively, a layer other than the nitride semiconductor light-emitting layer 12 may be provided on the nitride semiconductor film 112, and the nitride semiconductor light-emitting layer 12 may be provided on the layer. The formation position of the nitride semiconductor light-emitting layer 12 is not particularly limited. Specifically, an undoped AlGaN layer may be provided on the nitride semiconductor film 112, and the nitride semiconductor light-emitting layer 12 may be provided on the undoped AlGaN layer.

The nitride semiconductor light-emitting layer 12 is not particularly limited as long as it is a nitride semiconductor layer, but is preferably a mixed crystal of AlN, GaN, and InN from the viewpoint of achievement of high luminous efficiency. The nitride semiconductor light-emitting layer 12 may contain, in addition to nitrogen (N), other group V elements such as P, As, and Sb, and impurities such as C, H, F, O, Mg, and Si. Additionally, the nitride semiconductor light-emitting layer 12 may have either a quantum well structure or a single layer structure, but has preferably at least one well structure from the viewpoint of achievement of high luminous efficiency.

<P-Type Second Nitride Semiconductor Layer>

As illustrated in FIG. 1, the p-type second nitride semiconductor layer 13 may be provided directly on the nitride semiconductor light-emitting layer 12. Alternatively, a layer other than the p-type second nitride semiconductor layer 13 may be provided on the nitride semiconductor light-emitting layer 12, and the p-type second nitride semiconductor layer 13 may be provided on the layer. For example, a graded composition layer in which a ratio of constituent elements varies continuously or discretely may be provided on the nitride semiconductor light-emitting layer 12, and the p-type second nitride semiconductor layer 13 may be provided on the graded composition layer.

The formation position of the p-type second nitride semiconductor layer 13 is not particularly limited. The nitride semiconductor light-emitting element 1 may further include a barrier layer with a relatively large bandgap between the nitride semiconductor light-emitting layer 12 and the graded composition layer. Additionally, in another form of the nitride semiconductor light-emitting element 1, the p-type second nitride semiconductor layer 13 may be provided directly or indirectly on the substrate 10.

<Protective Film>

The nitride semiconductor light-emitting element 1 according to the present embodiment includes the protective film 19 formed of silicon nitride. Materials for forming the protective film 19 include silicon oxide, aluminum oxide, and the like, in addition to silicon nitride. Additionally, the protective film 19 may have a multilayer structure in which layers formed of those materials are combined (laminated).

The method for forming the protective film 19 is not particularly limited, but the protective film 19 can be formed by, for example, a plasma CVD device, a sputtering device, a vacuum deposition device, or the like. From a viewpoint of productivity and stress on the device, the protective film 19 has a film thickness of preferably from 10 nm to 1000 nm, and more preferably from 50 nm to 500 nm.

<Electrodes>

The nitride semiconductor light-emitting element 1 according to the present embodiment includes the n-type electrodes (an example of the first electrode) 15a, 15b, 15c, 15d, and 15e arranged so that contact interfaces with the first nitride semiconductor layer 11 are first contact regions 151a, 151b, 151c, 151d, and 151e extending in a first direction L1. Additionally, the nitride semiconductor light-emitting element 1 includes the p-type electrodes 16a and 16c (an example of the second electrode) (or the p-type electrodes 16b and 16d (an example of the second electrode)) arranged so that contact interfaces with the second nitride semiconductor layer 13 are second contact regions 161a and 161c (or second contact regions 161b and 161d) extending in the first direction L1. Furthermore, the nitride semiconductor light-emitting element 1 includes the p-type electrodes 16b and 16d (an example of the third electrode) (or the p-type electrodes 16a and 16c (an example of the third electrode)) in which contact interfaces with the second nitride semiconductor layer 13 provided in the semiconductor laminated portions 10b and 10d (an example of the second semiconductor laminated portion) (or the semiconductor laminated portions 10a and 10c (an example of the second semiconductor laminated portion)) are third contact regions 161b and 161d (or the second contact regions 161a and 161c) extending in the first direction L1 and which are arranged to sandwich the n-type electrodes 15b, 15c, and 15d together with the p-type electrodes 16a and 16c (or the p-type electrodes 16b and 16d (an example of the second electrode)).

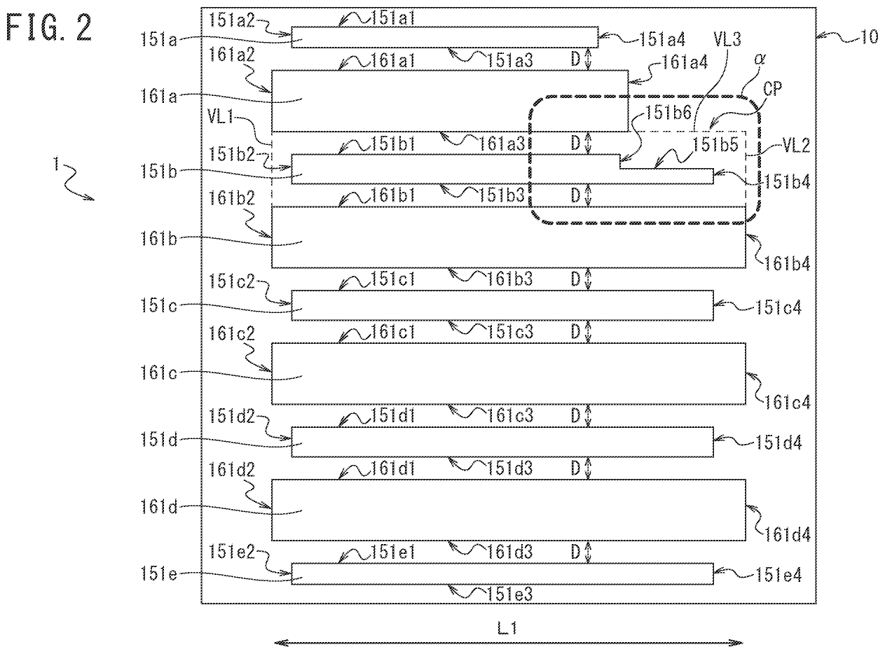

Here, the first direction L1 is a direction parallel to an outer peripheral end of the substrate 10 intersecting a direction in which the n-type electrodes 15a to 15e and the p-type electrodes 16a to 16d are arranged (see FIG. 2). Among the p-type electrodes 16a to 16d, the p-type electrodes arranged on the semiconductor laminated portions 10a to 10d corresponding to the first semiconductor laminated portion correspond to the second electrode. In addition, among the p-type electrodes 16a to 16d, the p-type electrodes arranged on the semiconductor laminated portions 10a to 10d corresponding to the second semiconductor laminated portion correspond to the third electrode. For example, when the semiconductor laminated portion 10a and the semiconductor laminated portion 10c correspond to the first semiconductor laminated portion and the semiconductor laminated portion 10b and the semiconductor laminated portion 10d correspond to the second semiconductor laminated portion, the p-type electrode 16a and the p-type electrode c correspond to the second electrode, and the p-type electrode 16b and the p-type electrode 16d correspond to the third electrode. In addition, for example, when the semiconductor laminated portion 10b and the semiconductor laminated portion 10d correspond to the first semiconductor laminated portion and the semiconductor laminated portion 10a and the semiconductor laminated portion 10c correspond to the second semiconductor laminated portion, the p-type electrode 16b and the p-type electrode d correspond to the second electrode, and the p-type electrode 16a and the p-type electrode 16c correspond to the third electrode. Thus, to give an example, for example, the p-type electrode 16b corresponding to the third electrode is arranged to sandwich the n-type electrode 15b corresponding to the first electrode together with the p-type electrode 16a corresponding to the second electrode, and is arranged to sandwich the n-type electrode 15c corresponding to the first electrode together with the p-type electrode 16c corresponding to the second electrode.

The n-type electrodes 15a to 15e and the p-type electrodes 16a to 16d are provided to supply power to the nitride semiconductor light-emitting layer 12. The n-type electrodes 15a to 15e are formed on an upper surface of the base portion 110 (a surface thereof on a side where the substrate 10 is not arranged). The p-type electrodes 16a to 16d are formed on a top surface of the mesa portion 31 (a surface of the second nitride semiconductor layer 13 on a side where the substrate 10 is not arranged). Materials that can be used to form the n-type electrodes 15a to 15e include titanium (Ti), aluminum (Al), nickel (Ni), chromium (Cr), vanadium (V), zirconium (Zr), gold (Au), hafnium (Hf), hemoglobin (Nb), tantalum (Ta), molybdenum (mo), tungsten (W), and alloys thereof. Additionally, materials that can be used to form the p-type electrodes 16a to 16d include Ni, platinum (Pt), silver (Ag), Au, rhodium (Rh), palladium (Pd), and alloys thereof.

The nitride semiconductor light-emitting element 1 includes the pad electrodes 17a to 17e arranged in contact with parts of the n-type electrodes 15a to 15e exposed from the protective film 19. The pad electrode 17a is arranged in contact with the n-type electrode 15a, the pad electrode 17b is arranged in contact with the n-type electrode 15b, the pad electrode 17c is arranged in contact with the n-type electrode 15c, the pad electrode 17d is arranged in contact with the n-type electrode 15d, and the pad electrode 17e is arranged in contact with the n-type electrode 15e. The nitride semiconductor light-emitting element 1 includes the pad electrodes 18a to 18d arranged in contact with parts of the p-type electrodes 16a to 16d exposed from the protective film 19. The pad electrode 18a is arranged in contact with the p-type electrode 16a, the pad electrode 18b is arranged in contact with the p-type electrode 16b, the pad electrode 18c is arranged in contact with the p-type electrode 16c, and the pad electrode 18d is arranged in contact with the p-type electrode 16d. Materials for forming the pad electrodes 17a to 17e and 18a to 18d include Au, Al, Ag, and the like, but Au is preferable because of its high conductivity.

<Planar Shape>

Next, a main part of a planar shape of the nitride semiconductor light-emitting element 1 is described with reference to FIG. 1 and using FIG. 2. For ease of understanding, FIG. 2 illustrates only the substrate 10 and the respective planar shapes of the first contact regions 151a to 151e, the second contact regions 161a and 161c (or the second contact regions 161b and 161d), and the third contact regions 161b and 161d (or the third contact regions 161a and 161c).

The first contact regions 151a to 151e are contact interface regions where the n-type electrodes 15a to 15e contact the first nitride semiconductor layer 11. Therefore, the first contact region 151a also represents the planar shape of the n-type electrode 15a, the first contact region 151b also represents the planar shape of the n-type electrode 15b, the first contact region 151c also represents the planar shape of the n-type electrode 15c, the first contact region 151d also represents the planar shape of the n-type electrode 15d, and the first contact region 151e also represents the planar shape of the n-type electrode 15e.

The second contact regions 161a and 161c (or the second contact regions 161b and 161d) are contact interface regions where the p-type electrodes 16a and 16c (or the p-type electrodes 16b and 16d) contact the second nitride semiconductor layer 13 provided in each of the semiconductor laminated portions 10a and 10c (or the semiconductor laminated portions 10b and 10d) corresponding to the second semiconductor laminated portion. Additionally, in this case, the third contact regions 161b and 161d (or the third contact regions 161a and 161c) are contact interface regions where the p-type electrodes 16b and 16d (or the p-type electrodes 16a and 16c) contact the second nitride semiconductor layer 13 provided in each of the semiconductor laminated portions 10b and 10d (or the semiconductor laminated portions 10a and 10c) corresponding to the third semiconductor laminated portion. Therefore, the second contact region 161a also represents the planar shape of the p-type electrode 16a, the second contact region 161b also represents the planar shape of the p-type electrode 16b, the second contact region 161c also represents the planar shape of the p-type electrode 16c, and the second contact region 161d also represents the planar shape of the p-type electrode 16d.

The following description is given by assuming that the semiconductor laminated portions 10a and 10c correspond to the second semiconductor laminated portion, the semiconductor laminated portions 10b and 10d correspond to the third semiconductor laminated portion, the p-type electrodes 16a and 16c correspond to the second electrode, and the p-type electrodes 16b and 16d correspond to the third electrode. Thus, hereinafter, it is assumed to be the second contact regions 161a and 161c and the third contact regions 161b and 161d.

As illustrated in FIG. 2, the substrate 10 included in the nitride semiconductor light-emitting element 1 has, for example, a square shape. In plan view, the nitride semiconductor light-emitting element 1 includes five (one or more) first contact regions 151a to 151e extending in the first direction, at least two second contact regions 161a and 161c, and at least two third contact regions 161b and 161d. Here, the plan view is a thickness direction of the substrate 10. In other words, the plan view is a direction orthogonal to a plane of the substrate 10 where the semiconductor laminated portions 10a to 10d are formed.

When a distance between the n-type electrodes 15a to 15e and the p-type electrodes 16a to 16d adjacent to each of the n-type electrodes 15a to 15e (inter-electrode distance) is too short, processing variations may cause a short circuit. On the other hand, when the inter-electrode distance is too long, a resistance component between the n-type electrodes 15a to 15e and the p-type electrodes 16a to 16d adjacent to each of the n-type electrodes 15a to 15e increases, leading to deterioration of the electrical characteristics of the nitride semiconductor light-emitting element 1. Therefore, an inter-region distance D (see FIG. 2) corresponding to the inter-electrode distance is preferably from 2 μm to 40 μm. Additionally, each inter-electrode distance may not be the same but may be different.

Each of the n-type electrodes 15a to 15e and the p-type electrodes 16a to 16d in the present embodiment has a substantially rectangular shape in plan view. Therefore, as illustrated in FIG. 2, the first contact regions 151a to 151e, the second contact region 161a and 161c, and the third contact regions 161b and 161d also are substantially rectangular in shape. Here, “substantially rectangular” includes shapes in which four corners are not exactly 90°, but are removed and rounded off.

The n-type electrodes 15a to 15e and the p-type electrodes 16a to 16d are arranged substantially parallel to the first direction. In other words, the n-type electrodes 15a to 15e and the p-type electrodes 16a to 16d are arranged substantially parallel to the outer peripheral end of the substrate 10 intersecting the direction in which the n-type electrodes 15a to 15e and the p-type electrodes 16a to 16d are arranged. “Substantially parallel” means that a deviation (inclination from parallel) is less than 5°.

Regions where the first nitride semiconductor layer 11 (more specifically, the base portion 110) and the n-type electrodes 15a to 15e are in direct contact are the first contact regions 151a to 151e, regions where the second nitride semiconductor layer 13 provided in the semiconductor laminated portions 10a and 10c and the p-type electrodes 16a and 16c are in direct contact are the second contact regions 161a and 161c, and regions where the second nitride semiconductor layer 13 provided in the semiconductor laminated portions 10b and 10d and the p-type electrodes 16b and 16d are in direct contact are the third contact regions 161b and 161d. Here, “direct contact” means a state where the semiconductor layer and a metal layer of the electrode are in contact without intervening any other layer such as an insulating layer at the interface.

In addition, the first contact regions, the second contact regions, and the third contact regions are surfaces on the electrode side that are in contact with the semiconductor layer. Accordingly, the first contact region 151a is the surface of the n-type electrode 15a that is in contact with the first nitride semiconductor layer 11. The first contact region 151b is the surface of the n-type electrode 15b that is in contact with the first nitride semiconductor layer 11. The first contact region 151c is the surface of the n-type electrode 15c that is in contact with the first nitride semiconductor layer 11. The first contact region 151d is the surface of the n-type electrode 15d that is in contact with the first nitride semiconductor layer 11. The first contact region 151e is the surface of the n-type electrode 15e that is in contact with the first nitride semiconductor layer 11.

Additionally, the second contact region 161a is the surface of the p-type electrode 16a that is in contact with the second nitride semiconductor layer 13 provided in the semiconductor laminated portion 10a. The second contact region 161c is the surface of the p-type electrode 16c that is in contact with the second nitride semiconductor layer 13 provided in the semiconductor laminated portion 10c. The third contact region 161b is the surface of the p-type electrode 16b that is in contact with the second nitride semiconductor layer 13 provided in the semiconductor laminated portion 10b. The third contact region 161d is the surface of the p-type electrode 16d that is in contact with the second nitride semiconductor layer 13 provided in the semiconductor laminated portion 10d.

Since the n-type electrodes 15a to 15e are arranged substantially parallel to the first direction L1, the first contact regions 151a to 151e are also arranged substantially parallel to the first direction L1. Since the p-type electrodes 16a and 16c are arranged substantially parallel to the first direction L1, the second contact regions 161a and 161c are also arranged substantially parallel to the first direction L1. Since the p-type electrodes 16b and 16d are arranged substantially parallel to the first direction L1, the third contact regions 161b and 161d are also arranged substantially parallel to the first direction L1.

The first contact regions 151a to 151e extend only in one direction (e.g., the first direction L1), and do not extend in other directions. Additionally, the first contact regions 151a to 151e are arranged in parallel with a predetermined gap therebetween. Furthermore, the first contact regions 151a to 151e are arranged separately without contacting each other.

As illustrated in FIG. 2, a perimeter line of the first contact region 151a is composed of line segments 151a1, 151a2, 151a3, and 151a4. A perimeter line of the first contact region 151b is composed of line segments 151b1, 151b2, 151b3, 151b4, 151b5, and 151b6. A perimeter line of the first contact region 151c is composed of line segments 151c1, 151c2, 151c3, and 151c4. A perimeter line of the first contact region 151d is composed of line segments 151d1, 151d2, 151d3, and 151d4. A perimeter line of the first contact region 151e is composed of line segments 151e1, 151e2, 151e3, and 151e4.

A perimeter line of the second contact region 161a is composed of line segments 161a1, 161a2, 161a3, and 161a4. A perimeter line of the third contact region 161b is composed of line segments 161b1, 161b2, 161b3, and 161b4. A perimeter line of the second contact region 161c is composed of line segments 161c1, 161c2, 161c3, and 161c4. A perimeter line of the second contact region 161d is composed of line segments 161d1, 161d2, 161d3, and 161d4.

Therefore, as illustrated in FIG. 2, in plan view, a length of the line segment 151a3 (an example of a first line segment) of the perimeter lines of the first contact region 151a parallel to the first direction is shorter than a length of the line segment 161a1 (an example of a second line segment) of the perimeter line of the second contact region 161a parallel to the first direction and facing the first contact region 151a.

Additionally, in the plan view, a length of the line segment 151b1 (an example of the first line segment) of the perimeter line of the first contact region 151b parallel to the first direction L1 is shorter than a length of the line segment 161a3 (an example of the second line segment) of the perimeter line of the second contact region 161a parallel to the first direction L1 and facing the first contact region 151b. In the plan view, a length of the line segment 151b3 (an example of a third line segment) of the perimeter line of the first contact region 151b parallel to the first direction L1 and facing the line segment 151b1 is equal to or shorter than a length of the line segment 161b1 (an example of a fourth line segment) of the perimeter line of the third contact region 161b parallel to the first direction L1 and facing the first contact region 151b. In the nitride semiconductor light-emitting element 1 according to the present embodiment, the length of the line segment 151b3 is shorter than the length of the line segment 161b1.

In addition, in the plan view, a length of the line segment 151c3 (an example of the first line segment) of the perimeter line of the first contact region 151c parallel to the first direction L1 is shorter than a length of the line segment 161c1 (an example of the second line segment) of the perimeter line of the second contact region 161c parallel to the first direction L1 and facing the first contact region 151c. In the plan view, a length of the line segment 151c1 (an example of the third line segment) of the perimeter line of the first contact region 151c parallel to the first direction L1 and facing the line segment 151c3 is equal to or shorter than a length of the line segment 161b3 (an example of the fourth line segment) of the perimeter line of the third contact region 161b parallel to the first direction L1 and facing the first contact region 151c. In the nitride semiconductor light-emitting element 1 according to the present embodiment, the length of the line segment 151c1 is shorter than the length of the line segment 161b3.

Additionally, in the plan view, a length of the line segment 151d1 (an example of the first line segment) of the perimeter line of the first contact region 151d parallel to the first direction L1 is shorter than a length of the line segment 161c3 (an example of the second line segment) of the perimeter line of the second contact region 161c parallel to the first direction L1 and facing the first contact region 151d. In the plan view, a length of the line segment 151d3 (an example of the third line segment) of the perimeter line of the first contact region 151d parallel to the first direction L1 and facing the line segment 151d1 is equal to or shorter than a length of the line segment 161d1 (an example of the fourth line segment) of the perimeter line of the third contact region 161d parallel to the first direction L1 and facing the first contact region 151d. In the nitride semiconductor light-emitting element 1 according to the present embodiment, the length of the line segment 151d3 is shorter than the length of the line segment 161d1.

Here, when the third contact region 161d is taken as a second contact region with respect to the first contact region 151e, a length of the line segment 151e1 (an example of the first line segment) of the perimeter line of the first contact region 151e parallel to the first direction L1 in the plan view is shorter than a length of the line segment 161d3 (an example of the second line segment) of the perimeter line of the second contact region (i.e., the third contact region 161d) parallel to the first direction L1 and facing the first contact region 151e.

Thus, in the nitride semiconductor light-emitting element 1, the first contact region 151a has a shape in which the line segment 151a3 parallel to the first direction is shorter than the line segment 161a1 parallel to the first direction in the perimeter line of the second contact region 161a facing the first contact region 151a. Additionally, the first contact region 151b has a shape in which the line segment 151b1 parallel to the first direction L1 is shorter than the line segment 161a3 parallel to the first direction L1 in the perimeter line of the second contact region 161a facing the first contact region 151b, and the line segment 151b3 parallel to the first direction L1 is shorter than the line segment 161b1 parallel to the first direction L1 in the perimeter line of the third contact region 161b facing the first contact region 151b. In addition, the first contact region 151c has a shape in which the line segment 151c3 parallel to the first direction L1 is shorter than the line segment 161a1 parallel to the first direction L1 in the perimeter line of the second contact region 161c facing the first contact region 151c, and the line segment 151c1 parallel to the first direction L1 is shorter than the line segment 161b3 parallel to the first direction L1 in the perimeter line of the third contact region 161b facing the first contact region 151c. Furthermore, the first contact region 151d has a shape in which the line segment 151d1 parallel to the first direction L1 is shorter than the line segment 161c3 parallel to the first direction L1 in the perimeter line of the second contact region 161c facing the first contact region 151d, and the line segment 151d3 parallel to the first direction L1 is shorter than the line segment 161d1 parallel to the first direction L1 in the perimeter line of the third contact region 161d facing the first contact region 151d. Still furthermore, when the third contact region 161d is taken as a second contact region with respect to the first contact region 151e, the first contact region 151e has a shape in which the line segment 151e1 parallel to the first direction L1 is shorter than the line segment 161d3 parallel to the first direction L1 in the perimeter line of the second contact region (i.e., the third contact region 161d) facing the first contact region 151e.

Here, it is assumed that the length of each line segment is represented by adding the letter “L” to the signs of respective line segments of the first contact regions 151a to 151e, the second contact regions 161a and 161c, and the third contact regions 161b and 161d. For example, the length of the line segment 151a1 of the first contact region 151a is represented as “L151a1”. Then, each line segment parallel to the first direction L1 has the following relationship:
L153a3<L161a1
L151b1<L161a3
L151b3<L161b1
L151c1<L161b3
L151c3<L161c1
L151d1<L161c3
L151d3<L161d1
L151e1<L161d3

Here, in the present embodiment and each Examples and each Modification described later, “shorter than the length of the facing line segment” or “shorter than the facing line segment” means that when one line segment is vertically projected onto the other line segment, the one line segment has a relationship in which it is included in the other line segment. Additionally, “equal to or shorter than the length of the facing line segment” or “equal to or shorter than the facing line segment” means that when one line segment is vertically projected onto the other line segment, the two line segments have the same length.

Assume that in the nitride semiconductor light-emitting element 1, the n-type electrodes 15a to 15e (see FIG. 1) are subjected to the same potential as each other, and the p-type electrodes 16a to 16d (see FIG. 1) are subjected to an electric charge that is higher than the n-type electrodes 15a to 15e and that is the same as each other. In this case, current flows from the p-type electrode 16a to the n-type electrodes 15a and 15b via the semiconductor laminated portion 10a (see FIG. 1). Additionally, current flows from the p-type electrode 16b to the n-type electrodes 15b and 15c via the semiconductor laminated portion 10b (see FIG. 1). In addition, current flows from the p-type electrode 16c to the n-type electrodes 15c and 15d via the semiconductor laminated portion 10c (see FIG. 1). Furthermore, current flows from the p-type electrode 16d to the n-type electrodes 15d and 15e via the semiconductor laminated portion 10d (see FIG. 1).

When the length difference between the line segments 151a3 and 161a1 and the length difference between the line segments 151b1 and 161a3 are each too small, current is biased at end portions of the p-type electrode 16a (end portions near the line segments 161a2 and 161a4). When the differences are each too large, current does not fully spread to the end portions of the p-type electrode 16a, causing uneven light emission. Similarly, when the length difference between the line segments 151b3 and 161b1 and the length difference between the line segments 151c1 and 161b3 are each too small, current is biased at end portions of the p-type electrode 16b (end portions near the line segments 161b2 and 161b4). When the differences are each too large, current does not fully spread to the end portions of the p-type electrode 16b, causing uneven light emission. Similarly, when the length difference between the line segments 151c3 and 161c1 and the length difference between the line segments 151d1 and 161c3 are each too small, current is biased at end portions of the p-type electrode 16c (end portions near the line segments 161c2 and 161c4). When the differences are each too large, current does not fully spread to the end portions of the p-type electrode 16c, causing uneven light emission. Similarly, when the length difference between the line segments 151d3 and 161d1 and the length difference between the line segments 151e1 and 161d3 are each too small, current is biased at end portions of the p-type electrode 16d (end portions near the line segments 161d2 and 161d4). When the differences are each too large, current does not fully spread to the end portions of the p-type electrode 16d, causing uneven light emission.

Thus, in the nitride semiconductor light-emitting element 1 according to the present embodiment, these differences, i.e., the difference between the length of the first line segment and the length of the second line segment is preferably from 5 μm to 50 μm. More specifically, the difference between a length L151a3 of the line segment 151a3 and a length L161a1 of the line segment 161a1, the difference between a length L151b3 of the line segment 151b3 and a length L161b1 of the line segment 161b1, the difference between a length L151c3 of the line segment 151c3 and a length L161c1 of the line segment 161c1, and the difference between a length L151d3 of the line segment 151d3 and a length L161d1 of the line segment 161d1 are each preferably from 5 μm to 50 μm.

Additionally, in the nitride semiconductor light-emitting element 1 according to the present embodiment, the difference between the length of the third line segment and the length of the fourth line segment is preferably from 5 μm to 50 μm. More specifically, the difference between a length L151b3 of the line segment 151b3 and a length L161b1 of the line segment 161b1, the difference between a length L151c1 of the line segment 151c1 and a length L161b3 of the line segment 161b3, the difference between a length L151d3 of the line segment 151d3 and a length L161d1 of the line segment 161d1, and the difference between a length L151e1 of the line segment 151e1 and a length L161d3 of the line segment 161d3 are each preferably from 5 μm to 50 μm.

In addition, in the first contact region 151b, the length of the line segment 151b1 (an example of the first line segment) and the length of the line segment 151b3 (an example of the third line segment) may be different from each other. Furthermore, a length difference between the line segments 151b1 and 151b3 may be from 50 μm to 200 μm. Thus, by making different the lengths of the facing line segments 151b1 and 151b3 in the first contact region 151b, the amount of current flowing to each of the p-type electrode 16a including the facing second contact region 161a and the p-type electrode 16b including the facing third contact region 161b can be adjusted. Specifically, the amount of current flowing to the p-type electrode 16a including the second contact region 161a facing the shorter line segment 151b1 of the line segments 151b1 and 151b3 is reduced, which can prevent overcurrent from flowing to the p-type electrode 16a.

The length of the line segments 161a1 and 161a3 (an example of the second line segment) and the length of the line segments 161b1 and 161b3 (an example of the fourth line segment) may be different from each other. The length of the line segments 161c1 and 161c3 (an example of the second line segment) and the length of the line segments 161b1 and 161b3 (an example of the fourth line segment) may be different from each other. The length of the line segment 161d3 (an example of the second line segment) and the length of the line segments 161b1 and 161b3 (an example of the fourth line segment) may be different from each other. The length of the line segments 161a1 and 161a3 (an example of the second line segment) and the length of the line segment 161d1 (an example of the fourth line segment) may be different from each other. The length of the line segments 161c1 and 161c3 (an example of the second line segment) and the length of the line segment 161d1 (an example of the fourth line segment) may be different from each other. The length of the line segment 161d3 (an example of the second line segment) and the length of the line segment 161d1 (an example of the fourth line segment) may be different from each other.

A difference between the length of the line segments 161a1 and 161a3 (an example of the second line segment) and the length of the line segments 161b1 and 161b3 (an example of the fourth line segment) may be from 50 μm to 200 μm. A difference between the length of the line segments 161c1 and 161c3 (an example of the second line segment) and the length of the line segments 161b1 and 161b3 (an example of the fourth line segment) may be from 50 μm to 200 μm. A difference between the length of the line segment 161d3 (an example of the second line segment) and the length of the line segments 161b1 and 161b3 (an example of the fourth line segment) may be from 50 μm to 200 μm. A difference between the length of the line segments 161a1 and 161a3 (an example of the second line segment) and the length of the line segment 161d1 (an example of the fourth line segment) may be from 50 μm to 200 μm. A difference between the length of the line segments 161c1 and 161c3 (an example of the second line segment) and the length of the line segment 161d1 (an example of the fourth line segment) may be from 50 μm to 200 μm. A difference between the length of the line segment 161d3 (an example of the second line segment) and the length of the line segment 161d1 (an example of the fourth line segment) may be from 50 μm to 200 μm.

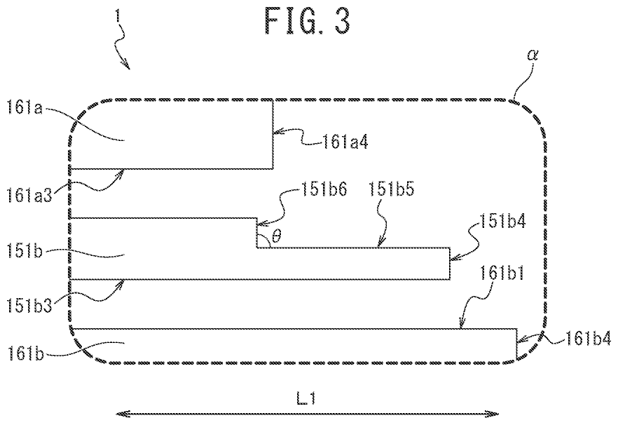

FIG. 3 is an enlarged view enlarging a range surrounded by a dashed line α illustrated in FIG. 2.

As illustrated in FIG. 3, in the nitride semiconductor light-emitting element 1, the line segments 151b5 and 151b6 are connected so that an angle θ between the line segments 151b5 and 151b6 of the perimeter line of the first contact region 151a is 90°, thereby making the first contact region 151b a closed space.

When the respective lengths L151a2, L151a4, L151b2, L151b4, L151b6, L151c2, L151c4, L151d2, L151d4, L151e2, and L151e4 of the line segments 151a2, 151a4, 151b2, 151b4, 151c2, 151c4, 151d2, 151d4, 151b6, 151e2, and 151e4 of the respective perimeter lines of the first contact regions 151a to 151d that are perpendicular to the first direction are too long, a chip size of the nitride semiconductor light-emitting element 1 is enlarged, and when the respective lengths thereof are too short, the n-type electrodes 15a to 15e tend to become highly resistive. Therefore, the lengths thereof are preferably from 5 μm to 100 μm. Additionally, the line segments 151a2, 151a4, 151b2, 151b4, 151b6, 151c2, 151c4, 151d2, 151d4, 151e2, and 151e4 may be the same or different in length. In addition, the line segments 151a2, 151a4, 151b2, 151b4, 151b6, 151c2, 151c4, 151d2, 151d4, 151e2, and 151e4 may not have an all straight line shape as illustrated in FIG. 2, but may have a curved shape with a part of the shape arcing or all thereof arcing.

In addition, when the respective lengths L161a2, L161a4, L161c2, and L161c5 of the line segments 161a2, 161a4, 161c2, and 161c5 of the respective perimeter lines of the second contact regions 161a and 161c that are perpendicular to the first direction are too long, uneven light emission occurs, and when the lengths thereof are too short, the p-type electrodes 16a and 16c tend to become highly resistive. Therefore, these lengths are preferably from 20 μm to 250 μm. Additionally, the line segments 161a2, 161a4, 161c2, and 161c5 may be the same or different in length. In addition, the line segments 161a2, 161a4, 161c2, and 161c5 may not have an all straight line shape as illustrated in FIG. 2, but may have a curved shape with a part of the shape arcing or all thereof arcing.

The first electrode 15b (see FIG. 1) arranged to be sandwiched by the second contact region 161a and the third contact region 161b may be arranged inside a convex polygon CP surrounding the second contact region 161a and the third contact region 161b in plan view. Here, a virtual line segment from an end portion of the line segment 161a2 on the first contact region 151b side to an end portion of the line segment 161b2 on the first contact region 151b side is defined as a first virtual line segment VL1. Additionally, a virtual line segment until a first virtual line extending in a direction perpendicular to the first direction L1 from an end portion of the line segment 161b4 on the first contact region 151b side intersects a second virtual line extending in the first direction L1 from an end portion of the line segment 161a4 on the first contact region 151b side is defined as a second virtual line segment VL2. Furthermore, a virtual line segment from the intersection of the second virtual line and the first virtual line to the end portion of the line segment 161a4 on the first contact region 151b side is defined as a third virtual line segment VL3. In the present embodiment, the convex polygon CP is a polygon formed by the line segment 161a1, the line segment 161a2, the virtual line segment VL1, the line segment 161b2, the line segment 161b3, the line segment 161b4, the virtual line segment VL2, the virtual line segment VL3, and the line segment 161a4. The convex polygon CP has a shape similar to the first contact region 151b.

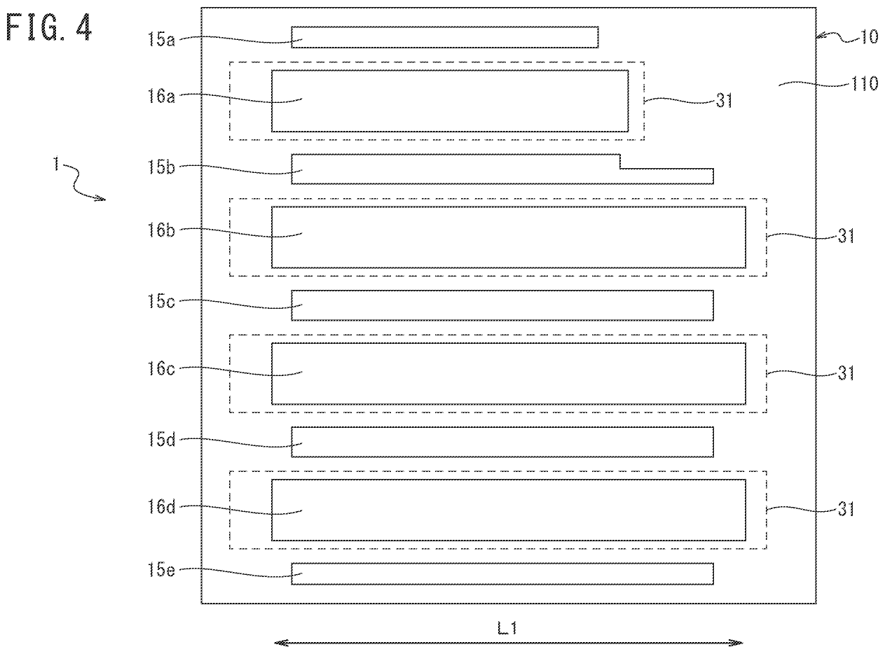

FIG. 4 is a schematic plan view illustrating a schematic configuration of the nitride semiconductor light-emitting element 1, and illustrates only the substrate 10, the base portion 110 and mesa portion 31 provided in the semiconductor laminated portions 10a to 10d (not illustrated in FIG. 4; see FIG. 1), the n-type electrodes 15a to 15e, and the p-type electrodes 16a to 16d among the components of the nitride semiconductor light-emitting element 1.

As illustrated in FIG. 4, in the nitride semiconductor light-emitting element 1, the mesa portion 31 provided in each of the semiconductor laminated portions 10a to 10d is provided separately in accordance with the arrangement of the p-type electrodes 16a to 16d.

### Examples

Hereinafter, the present invention is described more specifically with reference to Examples and Comparative Examples. It should be noted that the present invention is not limited to the following Examples.

Table 1 is a list showing distances between n-type and p-type electrodes (inter-electrode) and lengths (unit: μm) of respective line segments of first contact regions, second contact regions, and third contact regions provided in nitride semiconductor light-emitting elements according to Examples 1 to 3 and Comparative Example 1. “Inter-electrode” in Table 1 also indicates a distance between regions adjacent to each other among the first, second, and third contact regions. Additionally, “Sign” in Table 1 indicates an inter-electrode distance corresponding to the distance between the regions adjacent to each other among the first, second, and third contact regions and signs of each line segment indicated in FIG. 2 and FIGS. 5 to 7.

TABLE 1

| | | Length (unit: μm) | | | |
|---|---|---|---|---|---|
| | | Example | Example | Example | Comparative |
| | Sign | 1 | 2 | 3 | Example 1 |
| Inter-electrode | D | 15 | 15 | 15 | 15 |
| Line segment | 151a1, 151a3 | 398 | 398 | 432 | 432 |
| | 151b1 | 388 | 470 | 408 | 510 |
| | 151b3, 151c1, 151c3, 151d1, 151d3, 151e1, | 470 | 470 | 510 | 510 |
| | 151e3 | | | | |
| | 151a2, 151a4, 151e2, 151e4 | 20 | 20 | 20 | 20 |
| | 151b2, 151c2, 151c4, 151d2, 151d4 | 40 | 40 | 40 | 40 |
| | 151b4 | 20 | 40 | 20 | 40 |
| | 151b5 | 20 | — | 20 | — |
| | 151b6 | 82 | — | 102 | — |
| | 161a1, 161a3 | 438 | 438 | 438 | 438 |
| | 161b1, 161b3, 161c1, 161C3, 161d1, 161d3 | 510 | 510 | 510 | 510 |
| | 161a2, 161a4, 161b2, 161b4, 161c2, 161c4, | 70 | 70 | 70 | 70 |
| | 161d2, 161d4 | | | | |

Table 2 is a list showing simulation results of a maximum current density of current flowing between the n-type and p-type electrodes of the nitride semiconductor light-emitting elements according to Examples 1 to 3 and Comparative Example 1.

TABLE 2

| | Example | Example | Example | Comparative |
|---|---|---|---|---|
| | 1 | 2 | 3 | Example 1 |
| Maximum current | 412 | 485 | 435 | 493 |
| density | | | | |
| (Unit: A/cm²) | | | | |

### Example 1

A nitride semiconductor light-emitting element 1 according to Example 1 of the present embodiment has the same structure as the nitride semiconductor light-emitting element 1 described using FIGS. 1 and 2. Therefore, the nitride semiconductor light-emitting element 1 according to Example 1 is described with reference to FIG. 2.

In the nitride semiconductor light-emitting element 1 according to Example 1, the length of one side of the substrate 10 was set to 610 μm. The distance between the electrodes adjacent to each other (i.e., an inter-region distance D) among the n-type electrodes 15a to 15e (i.e., the first contact regions 151a to 151e), the p-type electrodes 16a and 16c (i.e., the second contact regions 161a and 161c), and the p-type electrodes 16b and 16d (i.e., the third contact regions 161b and 161d) and lengths of each line segment forming the respective perimeter lines of the first contact regions 151a to 151e, the second contact regions 161a and 161c, and the third contact regions 161b and 161d are as shown in the column of “Example 1” in Table 1.

In order to quantify current concentration, an evaluation was performed using a current diffusion simulation (software name: SpeCLED, manufactured by STR). For parameters of each resistance (sheet resistance of n-type semiconductor, sheet resistance of p-type semiconductor, contact resistance of n-type electrode, sheet resistance of n-type electrode, contact resistance of p-type electrode, and sheet resistance of p-type electrode), values obtained from the nitride semiconductor light-emitting element described in the embodiment were used, and a light emission wavelength of the nitride semiconductor light-emitting element 1 was set to 265 nm.

In order to quantify current concentration of the p-type electrodes 16a to 16d, current density values were used. Current density quantifies the amount of current per unit area, and a higher current density value indicates that more current concentration is occurring.

As shown in Table 2, in the nitride semiconductor light-emitting element 1 according to Example 1, when a current of 500 mA was applied, the maximum current density was 412 A/cm².

### Example 2

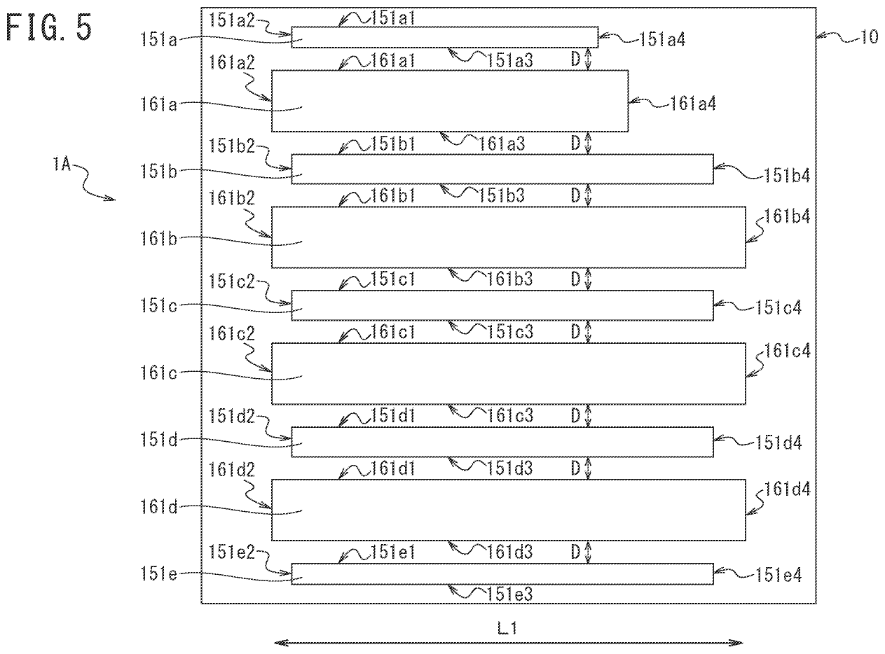

FIG. 5 is a diagram illustrating a main part of a planar shape of a nitride semiconductor light-emitting element 1A according to Example 2 of the present embodiment. For ease of understanding, FIG. 5 illustrates only the substrate 10 included in the nitride semiconductor light-emitting element 1A according to Example 2 and the respective planar shapes of the first contact regions 151a to 151e, the second contact regions 161a and 161c, and the third contact regions 161b and 161d. The nitride semiconductor light-emitting element 1A according to Example 2 has the same structure as the nitride semiconductor light-emitting element 1 according to Example 1 except that the shapes of the n-type electrode 15b and the first contact region 151b are different.

In the nitride semiconductor light-emitting element 1A according to Example 2, the length of one side of the substrate 10 was set to 610 μm. As illustrated in FIG. 5, in the nitride semiconductor light-emitting element 1A, the first contact region 151b has the same rectangular shape as the first contact regions 151c and 151d. Therefore, as shown in Table 1, the line segments 151b5 and 151b6 are not present in Example 2 (Table 2 indicates the absence thereof as “-”), and the length of the line segment 151b4 is 40 μm, which is the same as the length of the line segments 151c4 and 151d4.

In Example 2, a current diffusion simulation was performed with the same settings as in Example 1 except for the length of the line segment 151b4 of the first contact region 151b. As shown in Table 2, in the nitride semiconductor light-emitting element 1A according to Example 2, when a current of 500 mA was applied, the maximum current density value was 485 A/cm².

### Example 3

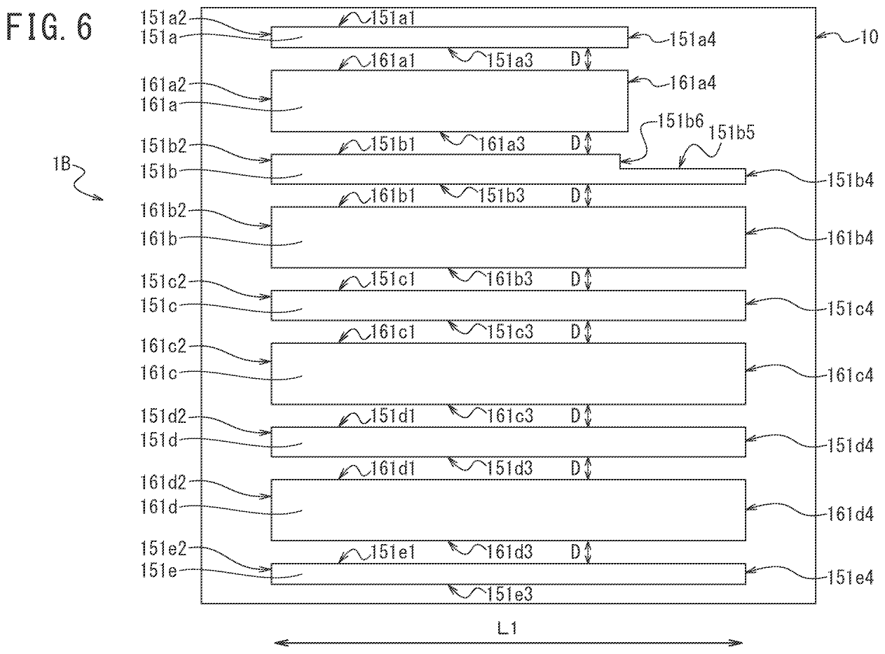

FIG. 6 is a diagram illustrating a main part of a planar shape of a nitride semiconductor light-emitting element 1B according to Example 3 of the present embodiment. For ease of understanding, FIG. 6 illustrates only the substrate 10 included in the nitride semiconductor light-emitting element 1B according to Example 3 and the respective planar shapes of the first contact regions 151a to 151e, the second contact regions 161a and 161c, and the third contact regions 161b and 161d. The nitride semiconductor light-emitting element 1B according to Example 3 has the same structure as the nitride semiconductor light-emitting element 1 according to Example 1 except that the line segments 151a, 151a3, 151b3, 151c1, 151c3, 151d1, 151d3, 151e1, and 151e3 have different lengths.

Specifically, the line segments 151a1 and 151a3 have the same length as the line segment 161a1, the line segment 151b3 has the same length as the line segment 161b1, the line segment 151c1 has the same length as the line segment 161b3, and the line segment 151c3 has the same length of the line segment 161c1. Additionally, the line segment 151d1 has the same length as the line segment 161c3, the line segment 151d3 has the same length as the line segment 161d1, and the line segments 151e1 and 151e3 have the same length as the line segment 161d3. Therefore, in Example 3, the first contact region 151b and the second and third contact regions 161a and 161b arranged to sandwich the first contact region 151b can have the same effect as the first contact region 151b and the second and third contact regions 161a and 161b arranged to sandwich the first contact region 151b in Example 1. However, the remaining first contact regions, second contact region, and third contact region in Example 3 are unlikely to have the same effect as the remaining first contact regions, second contact region, and third contact region in Example 1.

In the nitride semiconductor light-emitting element 1B according to Example 3, the length of one side of the substrate was set to 610 μm. As illustrated in FIG. 6, the line segments of the perimeter line of the first contact regions 151a to 151e in Example 3 that are parallel to the first direction L1 are equal in length to the line segments of the facing second or third contact regions in plan view, except for the line segment 151b1. Therefore, as shown in Table 1, in Example 3, the lengths of the line segments 151b3, 151c1, 151c3, 151d1, 151d3, 151e1, and 151e3 are 510 μm, which is the same as those of the line segments 161b1, 151b3, 151c1, 151c3, 151d1, and 161d3.

In Example 3, a current diffusion simulation was performed with the same settings as in Examples 1 and 2 except for the lengths of the line segments 151b3, 151c1, 151c3, 151d1, 151d3, 151e1, and 151e3. As shown in Table 2, in the nitride semiconductor light-emitting element 1B according to Example 3, when a current of 500 mA was applied, the maximum current density was 435 A/cm².

### Comparative Example 1

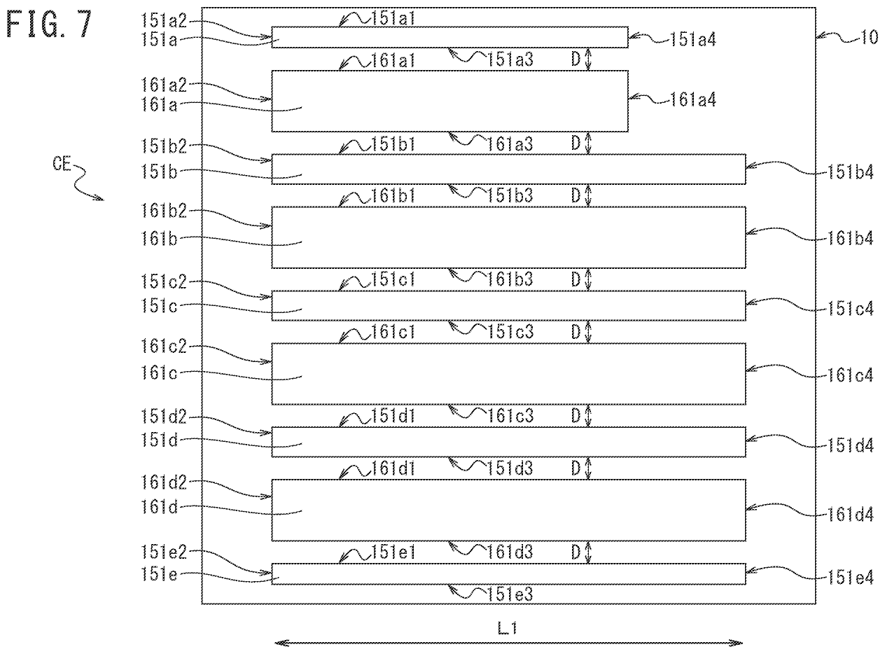

FIG. 7 is a diagram illustrating a main part of a planar shape of a nitride semiconductor light-emitting element CE according to Comparative Example 1. The nitride semiconductor light-emitting element CE according to Comparative Example 1 has the same structure as the nitride semiconductor light-emitting element 1B according to Example 3 except that the shape of the n-type electrode 15b and the first contact region 151b is different. Therefore, in the description of the nitride semiconductor light-emitting element CE according to Comparative Example 1, components of the nitride semiconductor light-emitting element CE are denoted by the signs used for the components of the nitride semiconductor light-emitting element 1B according to Example 3. For ease of understanding, FIG. 7 illustrates only the substrate 10 included in the nitride semiconductor light-emitting element CE according to Comparative Example 1 and the respective planar shapes of the first contact regions 151a to 151e, the second contact regions 161a and 161c, and the third contact regions 161b and 161d.

In the nitride semiconductor light-emitting element CE according to Comparative Example 1, the length of one side of the substrate 10 was set to 610 μm. As illustrated in FIG. 7, the first contact region 151b has a rectangular shape. Therefore, in Comparative Example 1, a current diffusion simulation was performed with the same settings as in Example 3 except that the length of the line segment 151b1 was 510 μm (see Table 1), which was the same as the length of the line segment 151b3. As shown in Table 2, in the nitride semiconductor light-emitting element CE according to Comparative Example 1, when a current of 500 mA was applied, the maximum current density value was 493 A/cm².

The results of Examples 1 to 3 and Comparative Example 1 show the following.

As in Comparative Example 1, when the lengths of the n-type electrodes in a longitudinal direction (i.e., the first direction L1) and the lengths of the p-type electrodes in the longitudinal direction (i.e., the first direction L1) were the same and there was no stepped portion formed in the n-type electrode, the maximum current density was 493 A/cm². On the other hand, as in Example 2, when the lengths of the n-type electrodes in the longitudinal direction (i.e., the first direction L1) were shorter than the lengths of the p-type electrodes in the longitudinal direction (i.e., the first direction L1) and there was no stepped portion formed in the n-type electrode, the maximum current density was 485 A/cm², which was smaller than the maximum current density in Comparative Example 1. Therefore, the nitride semiconductor light-emitting element 1A according to Example 2 can reduce current concentration compared to the nitride semiconductor light-emitting element CE according to Comparative Example 1.

Additionally, as in Example 3, when the lengths of the n-type electrodes in the longitudinal direction (i.e., the first direction L1) and the lengths of the p-type electrodes in the longitudinal direction (i.e., the first direction L1) were the same and a stepped portion was formed in the n-type electrode, the maximum current density was 435 A/cm², which was smaller than the maximum current density in Comparative Example 1. Therefore, the nitride semiconductor light-emitting element 1B according to Example 3 can reduce current concentration compared to the nitride semiconductor light-emitting element CE according to Comparative Example 1.

Furthermore, as in Example 1, when the lengths of the n-type electrodes in the longitudinal direction (i.e., the first direction L1) were shorter than the lengths of the p-type electrodes in the longitudinal direction (i.e., the first direction L1) and a stepped portion was formed in the n-type electrode, the maximum current density was 412 A/cm², which was smaller than the maximum current densities in each of Comparative Example 1 and Examples 2 and 3. Therefore, the nitride semiconductor light-emitting element 1 according to Example 1 can reduce current concentration most compared to the nitride semiconductor light-emitting elements according to each of Comparative Example land Examples 2 and 3.

Thus, by sandwiching the n-type electrodes 15a to 15e by the p-type electrodes 16a to 16d longer in longitudinal length than the n-type electrodes 15a to 15e, the nitride semiconductor light-emitting elements according to the present embodiment and Examples 1 to 3 can prevent current concentration in the p-type electrodes 16a to 16d without increasing voltage (i.e., drive voltage) applied between the n-type electrodes 15a to 15e and the p-type electrodes 16a to 16d.

In addition, since the n-type electrodes 15a to 15e and the p-type electrodes 16a to 16d in the present embodiment and Examples 1 to 3 can be formed without using any special manufacturing steps, the nitride semiconductor light-emitting elements according to the present embodiment and Examples 1 to 3 can prevent current concentration in the p-type electrodes 16a to 16d without increasing manufacturing steps.

Modification 1

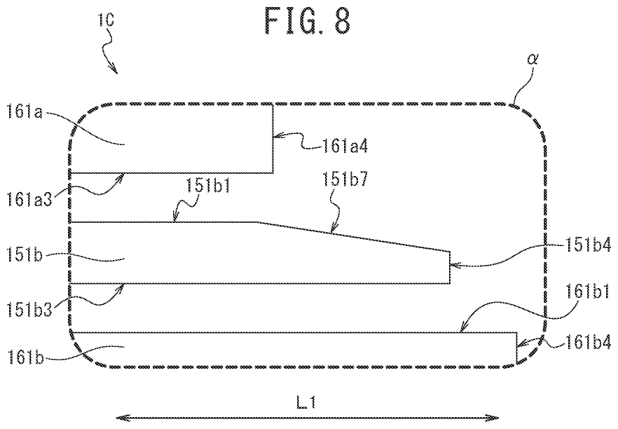

A nitride semiconductor light-emitting element 1C according to Modification 1 has the same structure as the nitride semiconductor light-emitting element 1 according the above embodiment except that the shape of the n-type electrode 15b and the first contact region 151b is different. FIG. 8 is a diagram illustrating a main part of a planar shape of the nitride semiconductor light-emitting element 1C according to Modification 1, and illustrates an enlarged view of a region corresponding to the dashed line α indicated in FIG. 2.

As illustrated in FIG. 8, in the nitride semiconductor light-emitting element 1C according to Modification 1, the line segment 151b1 and the line segment 151b4 of the first contact region 151b are connected by a line segment 151b7, thereby making the first contact region 151b a closed space. In this case, an angle between the line segments 151b1 and 151b7 is larger than 90° and smaller than 180°.

Even when the line segment on one end portion side of the first contact region 151b is not stepped but inclined, the length of the line segment 151b1 is shorter than the length of the line segment 161a3 forming the perimeter line of the second contact region 161a. This enables the nitride semiconductor light-emitting element 1C according to Modification 2 to obtain the same effect as the nitride semiconductor light-emitting element 1 according to the above embodiment.

Modification 2

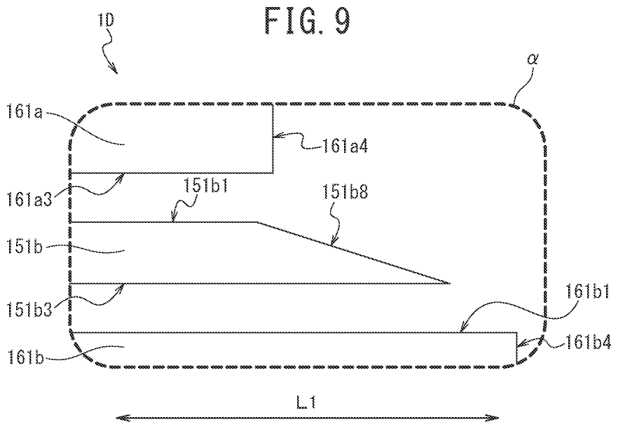

A nitride semiconductor light-emitting element 1D according to Modification 2 has the same structure as the nitride semiconductor light-emitting element 1 according the above embodiment except that the shape of the n-type electrode 15b and the first contact region 151b is different. FIG. 9 is a diagram illustrating a main part of a planar shape of the nitride semiconductor light-emitting element 1D according to Modification 2, and illustrates an enlarged view of a region corresponding to the dashed line α indicated in FIG. 2.

As illustrated in FIG. 9, in the nitride semiconductor light-emitting element 1D according to Modification 3, the line segment 151b1 and the line segment 151b3 of the first contact region 151b are connected by a line segment 151b8, thereby making the first contact region 151b a closed space. In this case, an angle between the line segments 151b1 and 151b8 is larger than 90° and smaller than 180°.

Even when the line segment on one end portion side of the first contact region 151b is not stepped but inclined, the length of the line segment 151b1 is shorter than the length of the line segment 161a3 forming the perimeter line of the second contact region 161a. This enables the nitride semiconductor light-emitting element 1D according to Modification 3 to obtain the same effect as the nitride semiconductor light-emitting element 1 according to the above embodiment.

Modification 3

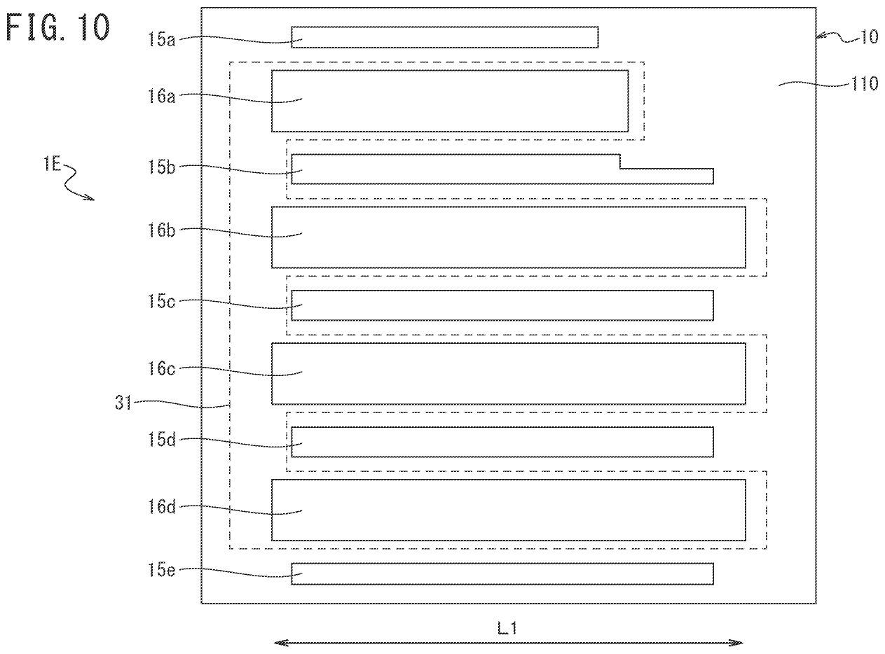

A nitride semiconductor light-emitting element 1E according to Modification 3 has the same structure as the nitride semiconductor light-emitting element 1 according the above embodiment except that the shape of the mesa portion 31 is different. FIG. 10 is a schematic plan view illustrating a schematic configuration of the nitride semiconductor light-emitting element 1E, and illustrates only the substrate 10, the base portion 110 and the mesa portion 31 provided in the semiconductor laminated portions 10a to 10d (not illustrated in FIG. 10; see FIG. 1), the n-type electrodes 15a to 15e, and the p-type electrodes 16a to 16d among the components of the nitride semiconductor light-emitting element 1E.

As illustrated in FIG. 10, in the nitride semiconductor light-emitting element 1E, the mesa portion 31 has a shape connected at one end portion side of the p-type electrodes 16a to 16d together with locations corresponding to each of the semiconductor laminated portions 10a to 10d. Even when the mesa portion 31 has such a structure, the nitride semiconductor light-emitting element 1E can obtain the same effect as the nitride semiconductor light-emitting element 1 according to the above embodiment.

As described above, the nitride semiconductor light-emitting element 1 according to the above embodiment includes the substrate 10, the first nitride semiconductor layer 11 formed on the substrate 10, the nitride semiconductor light-emitting layer 12 formed on the first nitride semiconductor layer 11, the semiconductor laminated portions 10a and 10b including the second nitride semiconductor layer 13 arranged on the nitride semiconductor light-emitting layer 12, the n-type electrodes 15a to 15e arranged so that the contact interfaces with the first nitride semiconductor layer 11 are the first contact regions 151a to 151e extending in the first direction L1, and the p-type electrodes 16a and 16c arranged so that the contact interfaces with the second nitride semiconductor layer 13 are the second contact regions 161a and 161c extending in the first direction L1, in which in plan view, the lengths of the line segments 151a3, 151b1, 151c3, and 151d1 of the perimeter lines of the first contact regions 151a to 151e parallel to the first direction L1 are shorter than the lengths of the line segments 161a1, 161a3, 161c1, and 161c3 of the perimeter lines of the second contact regions 161a and 161c parallel to the first direction L1 and facing the first contact regions 151a to 151d.

As a result, the nitride semiconductor light-emitting element 1 can suppress current concentration without increasing drive voltage or manufacturing steps.

Although the present invention has been described above using the embodiments, the technological scope of the present invention is not limited to the scope described in the above embodiments. It is obvious to those skilled in the art that various modifications or improvements can be made to the above embodiments. It is clear from the description of the claims that such modified or improved forms may also be included in the technological scope of the present invention.

It should be noted that the order of execution of each process, such as operation, procedure, step, and stage in the elements, systems, programs, and methods given in the claims, the specification, and the drawings can be realized in any order unless particularly indicated by “before”, “prior to”, or the like or an output of the previous process is used in a later process. Even when “first”, “next”, or the like is used for convenience in describing the flow of operations in the claims, the specification, and the drawings, it does not mean that it is essential to implement in this order.

### REFERENCE SIGNS LIST

1, 1A, 1B, 1C, 1D, 1E: Nitride semiconductor light-emitting element
10: Substrate
10a, 10b, 10c, 10d: Semiconductor laminated portion
11: First nitride semiconductor layer
12: Nitride semiconductor light-emitting layer
13: Second nitride semiconductor layer
15a, 15b, 15c, 15d, 15e: N-type electrode
16a, 16b 16c, 16d: P-type electrode
17a, 17b, 17c, 17d, 17e, 18a, 18b, 18c, 18d: Pad electrode
19: Protective film
31: Mesa portion
110: Base portion
111, 112: Nitride semiconductor film
151a, 151b, 151c, 151d, 151e: First contact region
151a1 to 151a4, 151b1 to 151b8, 151c1 to 151c4, 151d1 to 151d4, 151e1 to 151e4, 161a1 to 161a4, 161b1 to 161b4, 161c1 to 161c4, 161d1 to 161d4: Line segment
161a, 161c (161b, 161d): Second contact region
161b, 161d (161a, 161c): Third contact region

1. A nitride semiconductor light-emitting element comprising:
a substrate;
a first semiconductor laminated portion including a first nitride semiconductor layer formed on the substrate, a nitride semiconductor light-emitting layer formed on the first nitride semiconductor layer, and a second nitride semiconductor layer arranged on the nitride semiconductor light-emitting layer;
a first electrode arranged so that a contact interface with the first nitride semiconductor layer is a first contact region extending in a first direction; and
a second electrode arranged so that a contact interface with the second nitride semiconductor layer is a second contact region extending in the first direction,
wherein, in plan view, a length of a first line segment of a perimeter line of the first contact region parallel to the first direction is shorter than a length of a second line segment of a perimeter line of the second contact region parallel to the first direction and facing the first contact region.

2. The nitride semiconductor light-emitting element according to claim 1, wherein a difference between the length of the first line segment and the length of the second line segment is from 5 μm to 50 μm.

3. The nitride semiconductor light-emitting element according to claim 1, comprising:
a second semiconductor laminated portion including a first nitride semiconductor layer formed on the substrate, a nitride semiconductor light-emitting layer formed on the first nitride semiconductor layer, and a second nitride semiconductor layer arranged on the nitride semiconductor light-emitting layer; and
a third electrode arranged so that a contact interface with the second nitride semiconductor layer provided in the second semiconductor laminated portion is a third contact region extending in the first direction, and sandwiching the first electrode together with the second electrode,
wherein, in the plan view, a length of a third line segment of the perimeter line of the first contact region parallel to the first direction and facing the first line segment is equal to or shorter than a length of a fourth line segment of a perimeter line of the third contact region parallel to the first direction and facing the first contact region.

4. The nitride semiconductor light-emitting element according to claim 3, wherein the length of the first line segment and the length of the third line segment are different from each other.

5. The nitride semiconductor light-emitting element according to claim 4, wherein a difference between the length of the first line segment and the length of the third line segment is from 50 μm to 200 μm.

6. The nitride semiconductor light-emitting element according to claim 3, wherein the length of the second line segment and the length of the fourth line segment are different from each other.

7. The nitride semiconductor light-emitting element according to claim 6, wherein a difference between the length of the second line segment and the length of the fourth line segment is from 50 μm to 200 μm.

8. The nitride semiconductor light-emitting element according to claim 3, wherein the first electrode arranged to be sandwiched between the second contact region and the third contact region is arranged inside a convex polygon surrounding the second contact region and the third contact region in the plan view.

9. The nitride semiconductor light-emitting element according to claim 3, wherein the first nitride semiconductor layer provided in each of the first semiconductor laminated portion and the second semiconductor laminated portion has a layer thickness of from 200 nm to 1000 nm.

10. The nitride semiconductor light-emitting element according to claim 3, wherein the first nitride semiconductor layer provided in each of the first semiconductor laminated portion and the second semiconductor laminated portion is formed of AlₓGa₍₁₋ₓ₎N (x>0).
